(19) United States
(12) Patent Application Publication
(10) Pub. No.: US 2024/0063190 A1
(43) Pub. Date: Feb. 22, 2024

(54) LED CHIP TRANSFER METHOD AND DISPLAY PANEL

(71) Applicant: CHONGQING KONKA PHOTOELECTRIC TECHNOLOGY RESEARCH INSTITUTE CO., LTD., Chongqing (CN)

(72) Inventors: Xia DENG, Chongqing (CN); Chun-lung HSIAO, Chongqing (CN); Lijun CUI, Chongqing (CN)

(21) Appl. No.: 18/259,452

(22) PCT Filed: Aug. 10, 2021
(86) PCT No.: PCT/CN2021/111854

§ 371 Date: Jun. 27, 2023

(51) Int. Cl. H01L 25/075; H01L 33/48

(52) U.S. Cl. CPC H01L 25/0753; H01L 33/486

(57) ABSTRACT

The present disclosure relates to an LED chip transfer method and a display panel. The LED chip transfer method includes: setting a pyrolytic adhesive film on a chip bearing surface of a first substrate, the pyrolytic adhesive film covering a plurality of LED chips on the chip bearing surface; bonding one surface of a second substrate to the pyrolytic adhesive film, and separating the LED chips from the first substrate; picking up a target LED chip to be transferred on the second substrate by using a transfer head, and heating the pyrolytic adhesive film until the target LED chip is separated from the pyrolytic adhesive film; and bonding the target LED chip on the transfer head to a drive substrate.

### CROSS-REFERENCE TO RELATED APPLICATIONS

This application is a national phase application of International Application No. PCT/CN2021/111854, filed Aug. 10, 2021.

### TECHNICAL FIELD

The present disclosure relates to the field of displays, and in particular to an LED chip transfer method and a display panel.

### BACKGROUND

After an LED chip is prepared on a wafer, usually two or more transfers are required before the LED chip is bonded to a driving backplane to achieve a preparation of display panel. In a process of transferring the LED chip, it is not only necessary to combine the LED chip with a recipient carrier of the LED chip, but also to separate the LED chip from a donor carrier. However, the current LED chip transfer solutions either have the problem of unreliable combination of the LED chip and the recipient carrier, or the problem of difficult separation of the LED chip and the donor carrier, resulting in low transfer efficiency and transfer yield of LED chip.

Therefore, how to improve the transfer efficiency and transfer yield of LED chips is an urgent problem to be solved.

### SUMMARY

In view of the above shortcomings of the related technology, the purpose of the present disclosure is to provide an LED chip transfer method and a display panel, aiming to solve the problem of unreliable combination of the LED chip and the recipient carrier or difficult separation of the LED chip and the donor carrier for the transfer scheme of LED chip in the related technology.

The present disclosure provides an LED chip transfer method, including: setting a pyrolytic adhesive film on a chip bearing surface of a first substrate, the pyrolytic adhesive film covering a chip array on the chip bearing surface, the chip array including a plurality of LED chips arranged in an array; bonding one surface of a second substrate to one surface of the pyrolytic adhesive film away from the first substrate, and separating the chip array from the first substrate; picking up target LED chip to be transferred on the second substrate by using a transfer head, and heating the pyrolytic adhesive film until the target LED chip is separated from the pyrolytic adhesive film; and bonding the target LED chip on the transfer head to a drive substrate.

In the above LED chip transfer method, the pyrolytic adhesive film is set on the LED chips of the first substrate to cover the chip array on the chip bearing surface, and then one surface of the second substrate is used to bond the pyrolytic adhesive film, and the chip array is separated from the first substrate, so that the LED chips are transferred from the first substrate to the second substrate; and then the target LED chip to be transferred on the second substrate is picked up by the transfer head, and the pyrolytic adhesive film is heated until the target LED chip is separated from the pyrolytic adhesive film, thus allowing the target LED chip to be transferred to the transfer head and subsequently bonded to the drive substrate. During the whole transfer process of the LED chips, the pyrolytic adhesive film on the LED chips is used to achieve a reliable bonding between the LED chips and the second substrate, which improves the transfer yield of the LED chips from the first substrate to the second substrate; at the same time, one transfer between the second substrate and the pyrolytic adhesive film can transfer all LED chips on first substrate, which improves the transfer efficiency of LED chips from first substrate to second substrate. When using the transfer head to transfer the target LED chip to the drive substrate, the pyrolytic adhesive film which is bonded to the target LED chip can be invalidated by heating, so that the LED chips and the second substrate can be separated easily and quickly, which improves the transfer efficiency and transfer yield of LED chips from the second substrate to the drive substrate.

Based on same invention ideas, the present disclosure also provides a display panel. The display panel includes a drive substrate and a plurality of LED chips. A process of transferring at least part of the plurality of LED chips to the drive substrate includes: setting a pyrolytic adhesive film on a chip bearing surface of a first substrate, the pyrolytic adhesive film covering a chip array on the chip bearing surface, the chip array including a plurality of LED chips arranged in an array; bonding one surface of a second substrate to one surface of the pyrolytic adhesive film away from the first substrate, and separating the chip array from the first substrate; picking up target LED chip to be transferred on the second substrate by using a transfer head, and heating the pyrolytic adhesive film until the target LED chip is separated from the pyrolytic adhesive film; bonding the target LED chip on the transfer head to the drive substrate.

In the above display panel, the transfer process of at least part of the LED chips, the reliable bonding between the LED chips and the second substrate is achieved by using the pyrolytic adhesive film on the LED chips, which improves the transfer yield of the LED chips from first substrate to second substrate. At the same time, one transfer between the second substrate and the pyrolytic adhesive film can realize the transfer of all LED chips on the first substrate, which improves the transfer efficiency of the LED chips from the first substrate to the second substrate. When using the transfer head to transfer the target LED chip to the drive substrate, the pyrolytic adhesive film which is bonded to the target LED chip can be invalidated by heating, so that the LED chips and the second substrate can be separated easily and quickly, which improves the transfer efficiency and transfer yield of LED chips from the second substrate to the drive substrate, improves the production efficiency of the display panel, and reduces the production cost of display panel.

### BRIEF DESCRIPTION OF THE ACCOMPANYING DRAWINGS

FIG. 1 illustrates a flowchart of an LED chip transfer method according to one optional embodiment of the present disclosure;

FIG. 2 a schematic diagram of a change of a transfer state of the LED chip transfer method according to one optional embodiment of the present disclosure;

FIG. 3 a schematic diagram of a pyrolytic adhesive film covering a chip array illustrated in one optional embodiment of the present disclosure;

FIG. 4 is another schematic diagram of a pyrolytic adhesive film covering a chip array illustrated in one optional embodiment of the present disclosure;

FIG. 5 a structural schematic diagram of a display panel according to one optional embodiment of the present disclosure;

FIG. 6 illustrates a flowchart of an LED chip transfer method according to another optional embodiment of the present disclosure;

FIG. 7 is a schematic diagram of a change of a transfer state of the LED chip transfer method according to another optional embodiment of the present disclosure;

FIG. 8 is a schematic diagram of an array arrangement of LED chips on a wafer illustrated in another optional embodiment of the present disclosure.

### DESCRIPTION OF LABEL

20—first substrate; 21—LED chip; 22—pyrolytic adhesive film; 23—second substrate; 24—transfer head; 25—drive substrate; 50—display panel; 51—drive substrate; 52—LED chip; 71—wafer; 72—LED chip; 73—pyrolytic adhesive film; 74—second substrate; 75—PDMS stamp; 76—drive substrate.

### DETAILED DESCRIPTION OF ILLUSTRATED EMBODIMENTS

In order to facilitate the understanding of the present disclosure, the present disclosure will be more fully described below with reference to the relevant accompanying drawings. A preferred embodiment of the present disclosure is given in the accompanying drawings. However, the present disclosure can be implemented in many different forms and is not limited to the embodiments described herein. Rather, these embodiments are provided for the purpose of providing a more thorough and comprehensive understanding of the content of the present disclosure.

Unless otherwise defined, all technical and scientific terms used herein have the same meaning as commonly understood by those skilled in the art. The terms used herein in the specification of the present disclosure are for the purpose of describing specific embodiments only and are not intended to limit the present disclosure.

Micro-LED is the emerging display technology, relative to the conventional display technology, it has the characteristics of fast response, autonomous light-emitting, high contrast, long service life, high photoelectric efficiency, etc. Micro-LED display technology involves millions or even tens of millions of LED chips, for example, 4K display panel requires 25 million LED chips. Faced with the problem of transferring a huge number of LED chips, mass transfer was born, such as electrostatic adsorption technology, fluid assembly technology, roller embossing technology, Vanderwagen transfer technology, laser transfer technology, etc.

The LED chips, from a preparation to be set to a drive substrate, usually need to undergo two or even more transfers, it can be understood that in a process of transferring the LED chips from one carrier A to another carrier B, relative to the carrier B, the carrier A is a donor carrier of the LED chips, and relative to the carrier A, the carrier B is the recipient carrier of the LED chips. Of course, in the other transfer process that LED chips undergo, the role of the carrier A and the carrier B also change, for example, in the process of transferring the LED chips from the carrier B to the carrier C, the role of the carrier B becomes the donor carrier of the LED chips, while the recipient carrier of the LED chips is the carrier C. It should be understood that the donor carrier can be a substrate or a transfer device such as a transfer head, and similarly the recipient carrier can also be a substrate or a transfer device including a transfer head.

In an ideal transfer process, when the LED chips are transferred from the donor carrier to the recipient carrier, the LED chips should be able to be reliably combined with the recipient carrier, and at the same time can be easily and completely separated from the donor carrier. However, usually, the LED chips are either unreliably bonded to the recipient carrier, resulting in the LED chips not being transferred to the recipient carrier or easily detached from the recipient carrier; or it is too tightly bonded to the donor carrier and difficult to separate. Because of these problems, the transfer efficiency and transfer yield of LED chips are not high.

On the basis of this, the present disclosure wishes to provide a solution to the above technical problems, the details of which will be described in the subsequent embodiments.

An optional embodiment of the present disclosure:

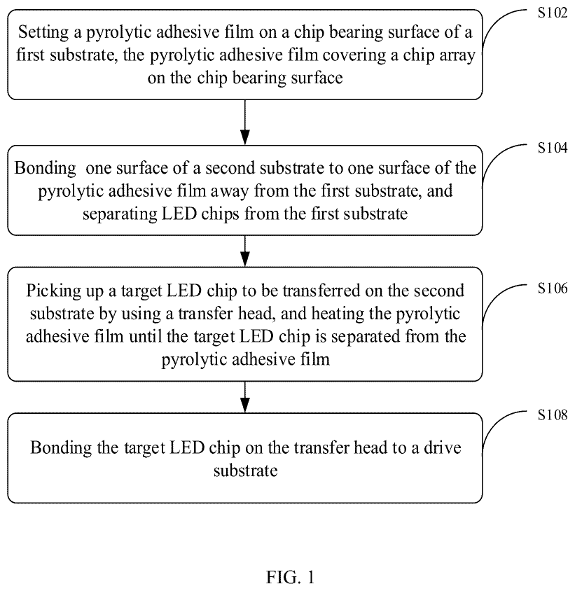

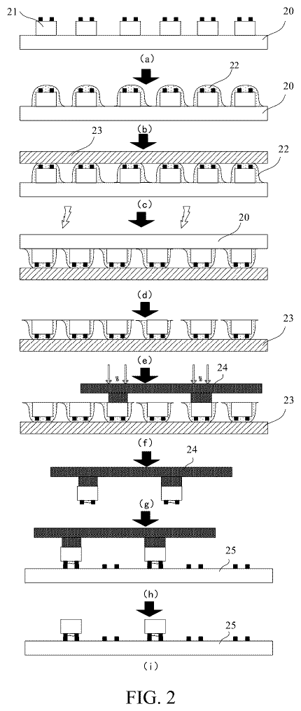

This embodiment first provides an LED chip transfer method. Referring to FIGS. 1 and 2, FIG. 1 illustrates a flowchart of the LED chip transfer method, and FIG. 2 illustrates a schematic diagram of a change of a transfer state of the LED chip transfer method:

S102: a pyrolytic adhesive film is set on a chip bearing surface of a first substrate, and the pyrolytic adhesive film covers a chip array on the chip bearing surface.

In (a) of FIG. 2, a first substrate 20 bearing a plurality of LED chips 21 is shown, and the plurality of LED chips 21 are arranged in an array on the first substrate 20 to form a chip array. It can be understood that the first substrate 20 can be a growth substrate for growing the LED chips 21, or it can be some substrate used in the process of transferring the LED chips 21, such as “temporary substrate” (also known as “transient substrate”, “transfer substrate”). The chip array is arranged on one surface of the first substrate 20. In this embodiment, a surface of the first substrate 20 used to bear the LED chips 21 is noted as “chip bearing surface”.

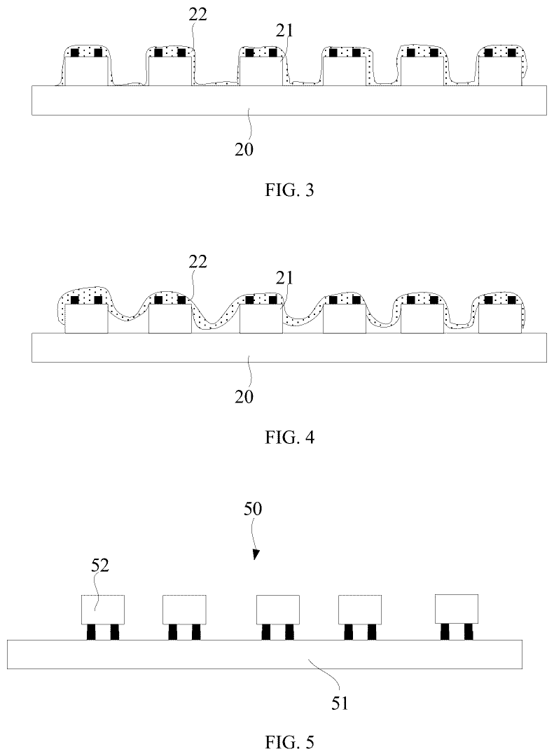

In (b) of FIG. 2, the pyrolytic adhesive film 22 is provided on the chip bearing surface of the first substrate 20, and the pyrolytic adhesive film 22 covers the chip array on the chip bearing surface. It can be understood that “cover” is not the same as “wrap”, which does not mean that pyrolytic adhesive film 22 covers all sides of the chip array at the same time to form an all-round wrap, as long as the pyrolytic adhesive film 22 covers the chip array and forms a certain surrounding potential for the chip array, the pyrolytic adhesive film 22 can be considered to cover the chip array. Of course, when the pyrolytic adhesive film 22 covers the chip array, it should usually be bonded to each LED chip in the chip array. Otherwise, there will be LED chips in the chip array that cannot rely on the pyrolytic adhesive film 22 to proceed the next transfer. In FIG. 2(b), the pyrolytic adhesive film 22 together with the first substrate 20 forms a full wrap around the chip array, which is one form of the pyrolytic adhesive film 22 covering the chip array. In other examples, the pyrolytic adhesive film 22 can cover the chip array in other forms, for example, see FIG. 3, another form of the pyrolytic adhesive film 22 covering the chip array is shown: the pyrolytic adhesive film 22 covers one side of the chip array away from the first substrate 20, while some areas extends down along a side of the edge LED chip in the chip array, and is attached to the first substrate 20. In yet another form of the pyrolytic adhesive film 22 covering the chip array shown in FIG. 4, the pyrolytic adhesive film 22 covers only one side of the chip array away from the first substrate 20 and some areas of a side of the edge LED chip and does not come into contact with the first substrate 20.

In some examples, the pyrolytic adhesive film 22 may be formed at other locations before being transferred to the chip array of the first substrate 20. In still other examples, the pyrolytic adhesive film 22 may also be formed directly on the first substrate 20, for example, the pyrolytic adhesive is directly set on the chip bearing surface of the first substrate 20 to form the pyrolytic adhesive film 22 covering the chip array. In one example, the pyrolytic adhesive film 22 can be formed by spraying the pyrolytic adhesive on the chip bearing surface of the first substrate 20. In another example, the pyrolytic adhesive film 22 can be formed by spin coating the pyrolytic adhesive on the chip bearing surface.

In this embodiment, the pyrolytic adhesive forming the pyrolytic adhesive film 22 may have a bonding temperature range of 80 to 150° C. and a debonding temperature range of 160 to 200° C. For example, in one example of this embodiment, the selected bonding temperature of the pyrolytic adhesive is 90 to 120° C. and the selected debonding temperature of the pyrolytic adhesive is 160 to 200° C.

In some examples of this embodiment, a thickness of a portion of the pyrolytic adhesive film 22 covering the LED chips 21 is 1˜3 um, for example, in one example, the thickness of the pyrolytic adhesive film 22 on the LED chips 21 is 1.8 um. Generally, a thickness of the micro-LED chip is about 7 um, so in these examples, the pyrolytic adhesive film 22 is not very thick, mainly because if the pyrolytic adhesive film 22 is too thick, then during the subsequent transfer of the LED chips 21, the pyrolytic adhesive film 22 needs to be heated and warmed up for a long time, which increases the difficulty of subsequent transfer. At the same time, the pyrolytic adhesive film 22 covering the chip array will be affected by gravity, so the pyrolytic adhesive film 22 between adjacent LED chips 21 will sink slightly, please continue to refer to (b) in FIG. 2, thus forming an encircling trend for single LED chip 21 as well. In this case, even though the thickness of the pyrolytic adhesive film 22 is small, it can form a more reliable bonding with the LED chips 21.

When the first substrate 20 is the growth substrate of the LED chips 21, a chip electrode of the LED chip 21 is usually set on one side of an epitaxial layer of the LED chip 21 away from the growth substrate, in this case, the pyrolytic adhesive film 22 covering on the LED chips 21 is covered and adhered to the chip electrodes of the LED chips 21. The pyrolytic adhesive film 22 covering the LED chips 21 is covered and adhered to the chip electrodes of the LED chips 21, as shown in (b) of FIG. 2.

S104: one surface of the second substrate is bonded to one surface of the pyrolytic adhesive film away from the first substrate, and the LED chips are separated from the first substrate.

After the pyrolytic adhesive film 22 is set up, the chip array needs to be transferred to the second substrate 23. In this embodiment, the second substrate can be a transient substrate (or “temporary substrate”, “transfer substrate”, etc.); the second substrate 23 is aligned with the first substrate 20, and then let the first substrate 20 and the second substrate 23 move towards to each other until one surface of the second substrate 23 is bonded to the pyrolytic adhesive film 22, as shown in (c) of FIG. 2. Usually, the second substrate 23 is moved in a direction towards the first substrate 20 until the second substrate 23 is bonded to the pyrolytic adhesive film 22. Since the bonding temperature of the pyrolytic adhesive film 22 is 80˜150° C., in the process of the second substrate 23 bonding to the pyrolytic adhesive film 22, a temperature environment of 80˜150° C. can be provided, in order to allow the pyrolytic adhesive film 22 to have a high adhesion force.

To further enhance a firmness of a bonding between the second substrate 23 and the pyrolytic adhesive film 22, in some examples of this embodiment, the pressure may also be applied to the second substrate 23 and/or the first substrate 20 toward each other, and the applied pressure may be in a range of 2 to 7 kg-m/s², for example, in one example of this embodiment, a pressure of 5 kg-m/s² may be applied to the second substrate 23 such that the second substrate 23 is moved toward the first substrate 20 and thus bonded to the pyrolytic adhesive film 22. In other examples, a pressure of 2 kg-m/s² can be applied from one side of the first substrate 20 away from second substrate 23 toward the second substrate 23, allowing the second substrate 23 to be tightly bonded to the pyrolytic adhesive film 22. In other examples, pressure may be applied to both the second substrate 23 and the first substrate 20 toward each other.

It should be appreciated that the process of bonding the second substrate 23 to the pyrolytic adhesive film 22 from the first substrate 20 can continue for a period of time, which can further increase a reliability of the bonding between the second substrate 23 and the pyrolytic adhesive film 22. For example, in some examples of this embodiment, this process may last from 1 to 5 min, and in some examples, this process will last from 1 to 2 min.

It can be understood that if the LED chips 21 are simply placed on the first substrate 20, then after the reliable bonding between the second substrate 23 and the pyrolytic adhesive film 22, the second substrate 23 can simply drive the chip array away from the first substrate 20 by using the pyrolytic adhesive film 22, thereby achieving an effect of transferring the LED chips 21 from the first substrate 20 to the second substrate 23 directly. However, generally, there is also a fixed connection between the first substrate 20 and the LED chips 21, in this case, in order to transfer the chip array from first substrate 20 to second substrate 23, in addition to using the pyrolytic adhesive film 22 to achieve the bonding between the chip array and the second substrate 23, the bonding between the LED chips 21 and the first substrate 20 should also be broken. In one example of this embodiment, the first substrate 20 is a sapphire substrate, for example, the first substrate 20 is a sapphire substrate for growing the epitaxial layers of the LED chips 21, at this time, LLO (laser peeling) can be selected to separate the LED chips 21 from the first substrate 20, please refer to (d) and (e) in FIG. 2. It can be understood that the peeling of the first substrate 20 should be done after a more reliable bonding between the pyrolytic adhesive film 22 and the second substrate 23.

S106: a target LED chip to be transferred on the second substrate is picked up by using a transfer head, and the pyrolytic adhesive film is heated until the target LED chip is separated from the pyrolytic adhesive film.

The peeling of the first substrate 20 marks that the LED chips 21 are transferred to the second substrate 23. Subsequently, the transfer head 24 can selectively pick up the LED chips 21 from second substrate 23 and transfer these selected LED chips 21 to the drive substrate 25. In this embodiment, the current LED chips 21 selected by the transfer head 24 to be transferred are referred to as the target LED chip. There is no doubt that the target LED chip is part of the chip array. The transfer head 24 selects the target LED chip based on the bonding requirements on the drive substrate 25. In some examples, the transfer head 24 may pick up the target LED chip based on electrostatic adsorption techniques; in other examples, the transfer head 24 may pick up the target LED chip based on Vandal force; in some examples, the transfer head 24 may pick up the target LED chip based on magnetic suction. In addition to this, the transfer head 24 can also bond the target LED chip via a gel. For example, in one example of this embodiment, the transfer head 24 can be a PDMS (Polydimethylsiloxane) stamp. The PDMS stamp is made by PDMS, this material can be deformed and also has a certain degree of adhesion. The PDMS stamp includes a plurality of bumps. The height of the bumps in the PDMS stamp for transferring Micro-LED chips can be 20˜30 um. Each bump is a pickup head, which can be used for adhesive pickup of a target LED chip at the same moment.

When the transfer head 24 picks up the target LED chip, especially when the transfer head 24 picks up the target LED chip based on a bonding way, the pressure applied to the second substrate 23 through the transfer head 24 can increase the reliability of bonding between the transfer head 24 and the target LED chip. Therefore, in these examples, the transfer head 24 can apply pressure to the target LED chip. Of course, because the forces are reciprocal, the pressure applied to the second substrate 23 towards the transfer head 24 is also equivalent.

In order to separate the target LED chip from the second substrate 23, the pyrolytic adhesive film 22 needs to be invalided, so when the transfer head 24 picks up the target LED chip, the pyrolytic adhesive film 22 can be heated. Optionally, in some examples, only the pyrolytic adhesive film 22 in the area corresponding to the target LED chip is heated, so that the adhesion of the pyrolytic adhesive film 22 only in the area where the target LED chip is bonded will be reduced, so that the transfer head 24 can also remove the target LED chip from the pyrolytic adhesive film 22. There are also examples where all areas of the pyrolytic adhesive film 22 can be heated, in which case the adhesion of the pyrolytic adhesive film 22 to all LED chips will be reduced, but because only the target LED chip is subjected to the adsorption force of the transfer head 24 or the adhesion force will break away from the pyrolytic adhesive film 22, while the remaining LED chips will still remain on the pyrolytic adhesive film 22.

In one example of this embodiment, the pyrolytic adhesive film 22 can be heated directly by laser or other means from one side of the second substrate 23 away from the chip array. In still other examples, the pyrolytic adhesive film 22 can also be heated directly using the transfer head 24, e.g., as shown in (f) in FIG. 2, the transfer head 24 applies pressure to the target LED chip and heats the target LED chip, and when the transfer head 24 is PDMS stamp, a temperature of a free end can be heated to 160˜200° C., and the temperature is conducted to the corresponding area of the pyrolytic adhesive film 22 through the target LED chip, which can make the adhesion of the pyrolytic adhesive film 22 to the target LED chip decrease or even disappear completely, so that the bonding between the target LED chip and the second substrate 23 is disrupted and the target LED chip is thus transferred to the transfer head 24, as in (g) in FIG. 2. In some examples of this embodiment, the duration of the transfer head 24 applying heating can be 1˜5 min, and in some examples, the transfer head 24 can move in the direction away from the second substrate 23 after applying heating to the target LED chip for 1˜2 min.

S108: the target LED chip on the transfer head is bonded to the drive substrate.

After the transfer head 24 picks up the target LED chip from the second substrate 23, the transfer head 24 can transfer the target LED chip to the drive substrate 25 and bond a chip electrode of the target LED chip to an on-board electrode on the drive substrate. As shown in (h) and (i) in FIG. 2, and the target LED chip is electrically connected to the drive circuit on the drive substrate 25 through the on-board electrode.

In some examples of this embodiment, the chip electrode of the target LED chip may be bonded to the on-board electrode on the drive substrate 25 by a bonding material. For example, the bonding material includes a solder or a conductive adhesive. In one example, solder including, but not limited to, gold-tin alloy, indium, and indium tinide is selected as the bonding material. In another example, of a conductive adhesive including a conductive silver adhesive, an ACF (Anisotropic Conductive Film), etc. may be selected as the bonding material.

In some examples of this embodiment, the transfer head 24 can bond the target LED chip to the drive substrate 25 with a bonding temperature of 120˜200° C. and a bonding pressure of 3˜8 kg-m/s². The time duration for the transfer head 24 bonding the target LED chip to the drive substrate 25 can last from 1˜5 min. For example, it can be selected to be completed in 1 to 2 min.

It can be understood that when the pyrolytic adhesive film 22 is set on the chip bearing surface of the first substrate 20, if the chip electrodes of the LED chips 21 are facing the pyrolytic adhesive film 22, then in the subsequent process, when the transfer head 24 picks up the target LED chip from the second substrate 23, there will be usually a small portion of pyrolytic adhesive remaining on the chip electrode of the target LED chip. In this case, the pyrolytic adhesive can act as a flux to some extent when soldering the chip electrode to the on-board electrode. In addition, when the bonding is completed, after the temperature around the chip electrode gradually decreases, the adhesion of the residual pyrolytic adhesive will be restored at least to some extent, which can enhance the bonding between the target LED chip and the drive substrate 25 and improve the chip transfer yield.

In some examples of this embodiment, after transferring the target LED chip to the drive substrate 25, in order to eliminate the influence of surface residual pyrolysis on the performance of the target LED chip, the residual pyrolysis on the target LED chip is also removed. In some examples, the residual pyrolysis adhesive can be removed after all the LED chips required for the drive substrate 25 have been transferred. The reference pyrolysis adhesive removal methods include at least two kinds of: first, the drive substrate 25 can be placed in a target chemical solution that reacts much less quickly with the epitaxial layers of LED chips, the chip electrodes, than it does with the pyrolytic adhesive; and even in some examples, the target chemical solution can be selected according to the materials of the epitaxial layer and the chip electrode in combination with the materials of the pyrolysis adhesive. Second, the residual pyrolysis adhesive on the LED chips can optionally be removed by plasma cleaning technology, e.g. the drive substrate 25 with the LED chips can be placed in a plasma device and then of oxygen and nitrogen gas is introduced to produce the corresponding plasma, which is then used to clean the residual pyrolysis adhesive on the LED chips.

This embodiment also provides a display panel. Referring to FIG. 5, FIG. 5 shows a schematic diagram of the display panel 50: the display panel 50 includes a drive substrate 51 and a plurality of LED chips 52. At least part of the plurality of LED chips 52 can be transferred to the drive substrate 51 by using the LED chip transfer method provided in the preceding example. At least some of the plurality of LED chips 52 can be transferred to the drive substrate 51 by the LED chip transfer method provided in the previous example. For the specific details of the transfer process of these LED chips, please refer to the introduction of the aforementioned example, which will not be repeated here.

The embodiment also provides an electronic device. The electronic device includes a processor and the aforementioned display panel. The processor is connected to the display panel by means of communication. The processor is able to control the display of the display panel. It can be understood that the electronic device can be a terminal such as a cell phone, a tablet, a laptop, a handheld computer, a personal digital assistant (PDA), a portable media player (PMP), a navigation device, a wearable device, a smart bracelet, a pedometer, or the like that includes the display panel. The electronic device can also be a fixed terminal such as a digital TV or a desktop computer that includes the display panel. It can be understood that the electronic device may include a RF (Radio Frequency) unit, a WiFi module, an audio output unit, a sensor, an interface unit, a memory and other components, in addition to the processor and the display panel.

The LED chip transfer method provided in this embodiment transfers the chip array on the first substrate to the transient substrate by using the pyrolytic adhesive film. By using the feature that the adhesion force of the pyrolytic adhesive has the ability to change with the change of temperature, during a process of transferring the LED chips, the adhesion force of the pyrolytic adhesive film can be controlled by temperature according to the demand of the adhesion force to the LED chips in a real-time transfer process, such that the LED chips can be tightly bonded to the corresponding recipient carrier through the pyrolytic adhesive film, and easily separated from the donor carrier, thus improving the transfer efficiency and transfer yield of the LED chips.

Furthermore, in this embodiment, the pyrolytic adhesive film itself is not thick, but because it covers each LED chip, therefore, the pyrolytic adhesive film provides sufficient adhesion to the LED chips without significantly increasing the difficulty and time cost of detaching the LED chips from the pyrolytic adhesive film, which is equivalent to using the pyrolytic adhesive film to form a “weakened structure” for transfer, and further enhances the transfer efficiency and transfer yields. Moreover, compared with other weakened structure setting process, this weakened structure setting process in this case is simple and convenient, low cost and high reliability.

Another optional embodiment of the present disclosure:

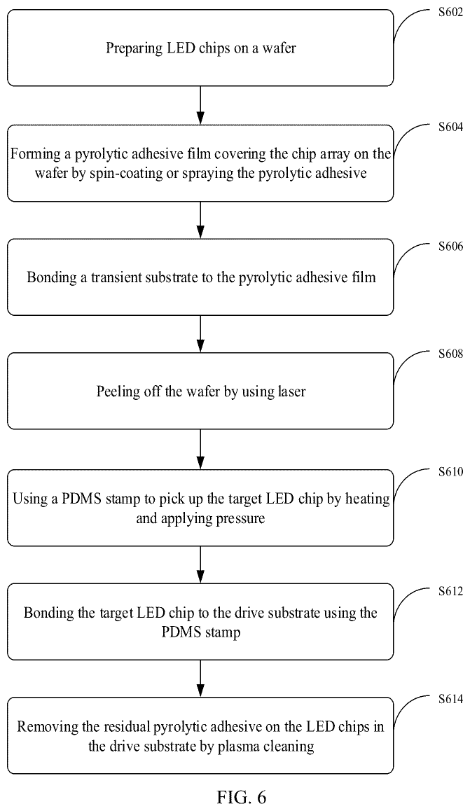

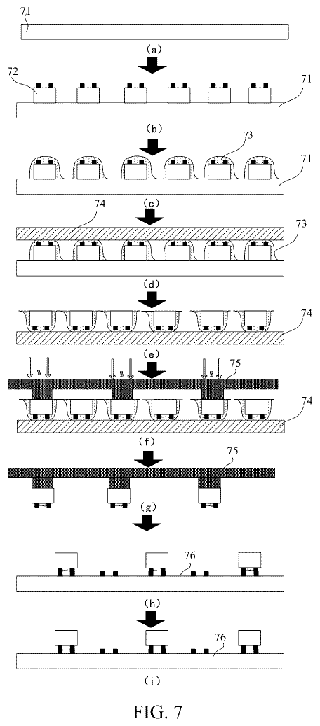

In order to make the advantages and details of the LED chip transfer method provided in each example of the preceding embodiments clearer to those skilled in the art, the LED chip transfer scheme will continue to be described in this embodiment in conjunction with the examples. Referring to FIGS. 6 and 7, FIG. 6 illustrates a flowchart of a process of an LED transfer method; FIG. 7 illustrates a schematic diagram of a change of a transfer state of the LED chip transfer method:

S602: the LED chips are prepared on a wafer.

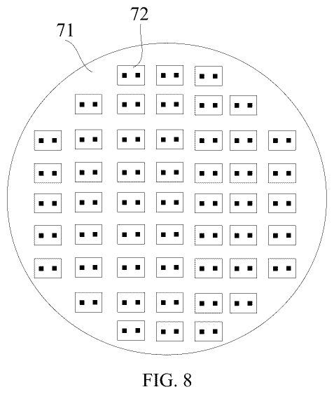

Firstly, please refer to (a) of FIG. 7, a wafer 71 is provided. In this embodiment, the materials of the wafer 71 can be sapphire. Of course, in some other examples, the wafer 71 can also be any one of gallium nitride substrate and silicon substrate. Then, the LED chips 72 are prepared on the wafer 71, as shown in (b) of FIG. 7, when preparing the LED chips 72 on the wafer 71, an epitaxial layer of the LED chip 72 can be grown on the wafer 71 firstly, and then the epitaxial layer is etched to form a plurality of sub-epitaxial layers, and then each sub-epitaxial layer is further etched to expose an electrode setting area. As can be seen in (b) of FIG. 7, the chip electrode of each LED chip 72 is located on one side of the epitaxial layer of the LED chip 72 away from the wafer 71. FIG. 8 illustrates a schematic diagram of the plurality of LED chips 72 arranged in an array on the wafer 71.

S604: the pyrolytic adhesive film covering the chip array is formed on the wafer by spin-coating or spraying the pyrolytic adhesive.

After the LED chips 72 are prepared, the pyrolytic adhesive film 73 can be formed by spraying or spin-coating the pyrolytic adhesive on the chip-bearing surface of the wafer 71. It can be understood that the wafer 71 in this embodiment is equivalent to the first substrate in the preceding embodiment. The pyrolytic adhesive film 73 covers the chip array, and at the same time forms an envelope for each LED chip 72 on the wafer 71. Since the chip electrode of LED chip 72 is backed towards the wafer 71, the pyrolytic adhesive film 73 is set to adhere to the chip electrode, see (c) in FIG. 7. The pyrolytic adhesive film 73 is not thick, e.g. in one example, the protruding thickness of the adhesive material on the top of the LED chips 72 (here the side of the LED chips 72 away from the wafer 71) is 1 to 3 um.

In this embodiment, the pyrolytic adhesive film 73 is formed with a pyrolytic adhesive bonding temperature 90 to 120° C. and a debonding temperature 160 to 200° C. Of course, in some other examples, other bonding temperatures or debonding temperatures can be chosen to form the pyrolytic adhesive film 73.

S606: a transient substrate is bonded to the pyrolytic adhesive film.

In FIG. 7(d), one side of the transient substrate 74 can be close to the wafer 71, the side of the transient substrate 74 is allowed to contact and bond to the pyrolytic adhesive film 73. In this embodiment, the transient substrate is the equivalent of the second substrate in the preceding embodiment. In order to enhance the adhesion of the transient substrate 74 to the pyrolytic adhesive film 73, the transient substrate 74 can be bonded to the pyrolytic adhesive film 73 at a bonding temperature of 90˜120° C. and a bonding pressure of 2˜5 kg-m/s². It can be understood that since the pyrolytic adhesive film 73 covers the chip array on the wafer 71, the transfer of the LED chips 72 from the wafer 71 by using the transient substrate 74 is a total transfer of the LED chips 72.

S608: the wafer is peeled off by using laser.

After the pyrolytic adhesive film 73 is bonded to the transient substrate 74, the wafer 71 can be peeled off. In this embodiment, since the wafer 71 is made of sapphire, the laser is selected to separate the LED chips 72 from the wafer 71, as shown in (e) of FIG. 7.

S610: the PDMS stamp is used to pick up the target LED chip by heating and applying pressure.

After transferring the chip array on the wafer 71 to the transient substrate 74, the chip can be selectively transferred from the transient substrate 74 to the drive substrate 76 by using the transfer head, and the transfer process is not indiscriminately targeted to all the LED chips 72 on the transient substrate 74. Specifically, the transfer head can select part of the LED chips 72 from the transient substrate 74 as the transfer target according to a transfer demand, i.e., part of the target LED chip is selected for transfer.

In some other examples of this embodiment, the transfer head can be a vacuum adsorption head, etc., or a magnetic suction head, etc. In this embodiment, the transfer head is PDMS stamp 75. The PDMS stamp 75 includes a plurality of bumps. A height of the bump is 20˜30 um. The spacing between the bumps can be set according to the transfer demand. After the bumps of the PDMS stamp 75 are aligned with the target LED chip on the transient substrate 74, pressure towards the transient substrate 74 can be applied to the PDMS stamp 75, for example, a pressure of 1˜6 kg-m/s², so that the bump and the target LED chip is more closely bonded together under the pressure. At the same time, the PDMS stamp 75 can also be used to heat the pyrolytic adhesive film 73 for example, the PDMS stamp 75 conducts heat through the bumps to the target LED chip, and then uses the target LED chip to continue to conduct heat to the pyrolytic adhesive film 73. In some examples of this embodiment, the temperature at the end of the bump can reach 160˜200° C., and the adhesion of the pyrolytic adhesive film 73 decreases after being heated. The process of applying pressure and heating of the PDMS stamp 75 can last 1˜2 min. After the adhesion force of the bumps to the target LED chip in the PDMS stamp 75 is greater than the adhesion force of the pyrolytic adhesive film 73 to the target LED chip, a force in a direction away from the transient substrate 74 is applied to the PDMS stamp 75, and then the target LED chip will be separated from the pyrolytic adhesive film 73, thereby transferrring the target LED chip from the transient substrate 74 to the PDMS stamp 75, refering to (f) and (g) of FIG. 7.

S612: the target LED chip is bonded to the drive substrate using the PDMS stamp.

After the PDMS stamp 75 picks up the target LED chip from the transient substrate 74, these target LED chip can be transferred to the drive substrate 76. The drive substrate 76 is set up with on-board electrodes corresponding to the chip electrodes of these target LED chip respectively. These on-board electrodes can have bonding materials such as solder or conductive adhesive. After the PDMS stamp 75 is moved to align the chip electrode of the target LED chip with the on-board electrode on the drive substrate 76, the target LED chip is bonded to the drive substrate 75 at a bonding temperature of 120˜200° C. and a bonding pressure of 3˜8 kg-m/s2. This bonding process can last 1˜2 min, as shown in (h) in FIG. 7.

From (g) in FIG. 7, it can be seen that some pyrolytic adhesive will remain on the chip electrode of the target LED chip and between the chip electrodes; some of these pyrolytic adhesives can play a role of flux when bonding the chip electrode to the on-board electrode in a soldering manner. Moreover, if these residual pyrolytic glues are not removed after the bonding of the target LED chip is completed, these pyrolytic glues can also enhance the bonding between the target LED chip and the drive substrate 76.

S614: the residual pyrolytic adhesive on the LED chips in the drive substrate is removed by plasma cleaning.

In order for the surface pyrolysis adhesive to not affect the performance of the LED chips 72, such as light output performance, etc. In this embodiment, the residual pyrolysis adhesive on the LED chips 72 is chosen to be removed after bonding the LED chips 72 to the drive substrate 76. In this embodiment, it is possible to place the drive substrate 76 into the plasma device after the solidification of the drive substrate 76 is all finished, and then oxygen is passed into the plasma device to generate oxygen plasma, and the residual pyrolysis adhesive is cleaned and removed using the oxygen plasma, as shown in (i) in FIG. 7.

It can be understood that the LED chip transfer scheme provided in this embodiment is not only applicable to the transfer of Micro-LED chips, but also to the transfer process of Mini-LED (mini-LED) chips as well as ordinary LED chips. It is not only applicable to the transfer of reverse-mount LED chips, but also applicable to the transfer of front-mount LED chips.

The LED chip transfer method provided in this embodiment not only forms the weakened structure required for the transfer process in a simple and fast way by setting the pyrolytic adhesive film 73 on the wafer 71, but also using the residual pyrolytic adhesive film 73 to flux in the process of bonding the LED chips 72 to the drive substrate 76, and strengthening the bonding force between the LED chips 72 and the drive substrate 76, thereby improving the transfer yield and transfer efficiency without increasing the transfer cost of the LED chips 72, improving the production efficiency and reducing the production cost. The pyrolytic adhesive film 73 can exist as a support structure of the LED chips 72, which can play a certain role of pressure resistance, and improve a pressure resistance of the display panel.

It should be understood that the application of the present disclosure is not limited to the above examples. For a person of ordinary skill in the art, the present disclosure can be improved or transformed according to the above description and all such improvements and transformations shall fall within the protection scope of the claims appended to the present disclosure.

What is claimed is:

1. An LED chip transfer method, comprising:
setting a pyrolytic adhesive film on a chip bearing surface of a first substrate, the pyrolytic adhesive film covering a chip array on the chip bearing surface, the chip array comprising a plurality of LED chips arranged in an array;
bonding one surface of a second substrate to one surface of the pyrolytic adhesive film away from the first substrate, and separating the chip array from the first substrate;
picking up a target LED chip to be transferred on the second substrate by using a transfer head, and heating the pyrolytic adhesive film until the target LED chip is separated from the pyrolytic adhesive film; and
bonding the target LED chip on the transfer head to a drive substrate.

2. The LED chip transfer method according to claim 1, wherein after bonding the target LED chip on the transfer head to the drive substrate, further comprising:
removing residual pyrolytic adhesive on the target LED chip.

3. The LED chip transfer method according to claim 2, wherein the removing residual pyrolytic adhesive on the target LED chip comprises:
generating a plasma by ionizing of oxygen and nitrogen, and using the plasma to clean the residual pyrolytic adhesive on the target LED chip.

4. The LED chip transfer method according to claim 1, wherein the setting the pyrolytic adhesive film on the chip bearing surface of the first substrate comprises:
setting a pyrolytic adhesive on the chip bearing surface of the first substrate to form the pyrolytic adhesive film covering the chip array.

5. The LED chip transfer method according to claim 4, wherein the setting the pyrolytic adhesive on the chip bearing surface of the first substrate to form the pyrolytic adhesive film covering the chip array comprises:
setting the pyrolytic adhesive on the chip bearing surface by means of spraying or spin coating, and forming the pyrolytic adhesive film covering the chip array.

6. The LED chip transfer method according to claim 1, wherein a part of the pyrolytic adhesive film covering the LED chips has a thickness of 1 to 3 um.

7. The LED chip transfer method according to claim 1, wherein the first substrate is a growth substrate for the LED chips; when the LED chips are located on the first substrate, a chip electrode of the LED chip is located on one side of an epitaxial layer of the LED chip away from the first substrate, the pyrolytic adhesive film is attached to the chip electrode.

8. The LED chip transfer method according to claim 7, wherein the growth substrate is a sapphire substrate, the separating the chip array from the first substrate comprises:
separating the chip array from the first substrate by using a laser.

9. The LED chip transfer method according to claim 1, wherein the bonding one surface of the second substrate to one surface of the pyrolytic adhesive film away from the first substrate comprises:
controlling the second substrate to bond to one surface of the pyrolytic adhesive film away from the first substrate at a temperature of 80 to 150° C. and a pressure of 2 to 7 kg-m/s².

10. The LED chip transfer method according to claim 9, wherein a bonding time duration of the second substrate bonding to the pyrolytic adhesive film is 1 to 5 min.

11. The LED chip transfer method according to claim 1, wherein the heating the pyrolytic adhesive film comprises
heating the pyrolytic adhesive film by using the transfer head.

12. The LED chip transfer method according to claim 11, wherein the picking up the target LED chip to be transferred on the second substrate by using the transfer head, and heating the pyrolytic adhesive film comprises:
applying pressure to the target LED chip by using the transfer head, and heating the pyrolytic adhesive film by using the transfer head until the target LED chip is adhered to the transfer head and is separated from the pyrolytic adhesive film;
wherein a temperature of heating the pyrolytic adhesive film is 160 to 200° C. and a pressure applied to the target LED chip is 1 to 6 kg-m/s².

13. The LED chip transfer method according to claim 12, wherein a time duration of heating and applying pressure on the pyrolytic adhesive film by using the transfer head is 1 to 5 min.

14. The LED chip transfer method according to claim 1, wherein the transfer head is a polydimethylsiloxane stamp.

15. The LED chip transfer method according to claim 14, wherein a height of a bump on the polydimethylsiloxane stamp is 20˜30 um.

16. The LED chip transfer method according to claim 1, wherein the bonding the target LED chip on the transfer head to the drive substrate comprises:
the transfer head bonding the target LED chip to the drive substrate at a bonding temperature of 120 to 200° C. and a bonding pressure of 3 to 8 kg-m/s².

17. The LED chip transfer method according to claim 16, wherein a time duration of bonding of the transfer head bonding the target LED chip to the drive substrate is 1 to 5 min.

18. A display panel, wherein the display panel comprises a drive substrate and a plurality of LED chips, a process of transferring at least part of the plurality of LED chips to the drive substrate comprises:
setting a pyrolytic adhesive film on a chip bearing surface of a first substrate, the pyrolytic adhesive film covering a chip array on the chip bearing surface, the chip array comprising a plurality of LED chips arranged in an array;
bonding one surface of a second substrate to one surface of the pyrolytic adhesive film away from the first substrate, and separating the chip array from the first substrate;
picking up a target LED chip to be transferred on the second substrate by using a transfer head and heating the pyrolytic adhesive film until the target LED chip is separated from the pyrolytic adhesive film;
bonding the target LED chip on the transfer head to the drive substrate.
